(19) United States
(12) Patent Application Publication
(10) Pub. No.: US 2026/0242977 A1
(43) Pub. Date: Aug. 20, 2026

(54) METHOD FOR GROWING ULTRA-LARGE-SIZE POLYCRYSTALLINE DIAMOND FILMS

(71) Applicant: Compound Semiconductor (Xiamen) Technology Co., Ltd., XIAMEN (CN)

(72) Inventors: Qi CHEN, XIAMEN (CN); Xing ZHANG, XIAMEN (CN)

(73) Assignee: Compound Semiconductor (Xiamen) Technology Co., Ltd., XIAMEN (CN)

(21) Appl. No.: 19/183,792

(22) Filed: Apr. 19, 2025

(30) Foreign Application Priority Data
Feb. 19, 2025 (CN) 202510181063.X

(51) Int. Cl. C30B 28/14; C30B 29/04; C30B 33/04

(52) U.S. Cl. CPC C30B 28/14; C30B 29/04; C30B 33/04

(57) ABSTRACT

A method for growing ultra-large-size polycrystalline diamond film includes: S1: cleaning and drying a monocrystalline silicon wafer at room temperature; S2: subjecting the wafer to a seeding pretreatment process to deposit a diamond nanocrystalline layer across a silicon surface, then transferring the wafer into a MPCVD equipment; S3: evacuating the chamber, performing hydrogen purging, then performing re-evacuation; subsequently, introducing hydrogen gas and regulating a pressure to 5-8 torr to initiate plasma ignition; S4: increasing microwave power to 70-75 kW with a rate of 4.5-5.5 kW/min, elevating the pressure to 165-180 torr with a rate of 10-30 torr/min, and increasing temperature to 900-950° C. with a rate of 60° C./min; S5: introducing growth gases with predetermined flow rates; S6: upon completion of diamond growth, cooling to room temperature, followed by venting the chamber with nitrogen gas, thereby obtaining the ultra-large-size polycrystalline diamond film.

### TECHNICAL FIELD

The present disclosure relates to a method for growing ultra-large-size polycrystalline diamond films, belonging to the technical field of semiconductor materials.

### BACKGROUND

Silicon-based devices refer to semiconductor components in electronic primarily composed of silicon material. With ever-increasing performance and functional demands in modern electronic apparatus, the power density of silicon devices has correspondingly intensified. Under high power density conditions, thermal generation per unit area/volume increases substantially. However, silicon exhibits relatively low thermal conductivity (typically about 100-120 W/mK), resulting in slower heat transfer within silicon-based devices. This inherent limitation impedes rapid thermal dissipation, and inefficient thermal transfer to the heat dissipation medium would lead to thermal accumulation within the silicon-based devices under high-power operation, thereby affecting device performance and operational reliability.

Currently, the primary method for growing polycrystalline diamond films is chemical vapor deposition (CVD). Among them, microwave plasma-enhanced chemical vapor deposition (MPCVD) has emerged as the dominant technique for synthesizing high-quality polycrystalline diamond films, owing to its advantages of avoiding electrode-induced contamination, precise controllability over reaction parameters, and so on. This technology enables the deposition of polycrystalline diamond films on substrate materials, establishing fundamental capabilities for large-area growth. However, existing MPCVD-based polycrystalline diamond film growth has the following drawbacks: (1) the existing polycrystalline diamond film growth exhibits limited deposition rates, especially for high-quality large-area films, resulting in prolonged growth duration, and such technical limitations inhibit scalability in industrial production and application while compromising cost-effectiveness, thereby diminishing market competitiveness; (2) while polycrystalline diamond films with some dimensions (e.g. 2-inch) have been successfully fabricated, their film size remains insufficient compared to conventional semiconductor substrates such as silicon wafer, posing challenges for applications in large-scale integrated circuits requiring large-area wafers; (3) achieving thickness uniformity and property consistency of polycrystalline diamond films across a large area remains technically challenging, and this spatial heterogeneity may induce performance divergence across different zones, substantially compromising their reliability in large-area devices; (4) even with successful growth of large-area polycrystalline diamond films, their poor quality renders them unsuitable for applications in large-scale devices.

### SUMMARY

The present disclosure provides a method for growing ultra-large-size polycrystalline diamond films, which can effectively address the aforementioned technical limitations.

The objective of the present disclosure is achieved by the following solution.

A method for growing ultra-large-size polycrystalline diamond film, comprising the following steps:
S1: cleaning and drying a monocrystalline silicon wafer at room temperature;
S2: subjecting the monocrystalline silicon wafer to a seeding pretreatment process to deposit a diamond nanocrystalline layer across a silicon surface, then transferring the seeded monocrystalline silicon wafer into a microwave plasma chemical vapor deposition (MPCVD) equipment, wherein the MPCVD equipment has a microwave source of 915 MHz or 433 MHz;
S3: evacuating a chamber of the MPCVD equipment, performing hydrogen purging, then performing re-evacuation; subsequently, introducing hydrogen gas and regulating a chamber pressure to 5-8 torr to initiate plasma ignition;
S4: increasing microwave power to 70-75 KW with a rate of 4.5-5.5 kW/min, elevating the chamber pressure to 165-180 torr with a rate of 10-30 torr/min, and increasing chamber temperature to 900-950° C. with a rate of 60° C./min;
S5: introducing growth gases with the following flow rates: hydrogen (H₂) at 5000-6000 sccm, methane (CH₄) at 100-150 sccm, oxygen (O₂) at 5-8 sccm, nitrogen (N₂) at 1-2 sccm, and argon (Ar) at 800-1000 sccm;
S6: upon completion of diamond growth, initiating a cooling process with a temperature decrease rate of 30° C./min until room temperature is reached, followed by venting the chamber with nitrogen gas, thereby obtaining the ultra-large-size polycrystalline diamond film.

In some embodiments, the cleaning process comprises sequential ultrasonic treatments of the monocrystalline silicon wafer in acetone, ethanol, and deionized water, respectively, and each treatment lasts for 15-30 minutes.

In some embodiments, the drying process comprises blow-drying the monocrystalline silicon wafer with inert gas to achieve surface dryness.

In some embodiments, the diamond nanocrystalline layer has a thickness of 10-50 nm.

In some embodiments, in the step of evacuating the chamber, a vacuum degree is less than 5 mtorr, and the evacuation is repeated for 3-5 times.

In some embodiments, after the step S6, the method further comprises S7, grinding and polishing a diamond surface of the ultra-large-size polycrystalline diamond film to achieve a surface roughness of ra<1 nm.

In some embodiments, after the step S7, the method further comprises S8, the polished ultra-large-size polycrystalline diamond film undergoing chemical silicon removal to substantially remove a silicon substrate and yield a pure diamond film.

In some embodiments, after the step S8, the method further comprises S9, the pure diamond film undergoing picosecond laser scribing to produce a high-quality diamond wafer.

In some embodiments, grinding and polishing a silicon surface of the ultra-large-size polycrystalline diamond film to achieve partial silicon removal while retaining a silicon substrate with a thickness of 5 nm to 10 μm.

According to another aspect, the present disclosure provides a ultra-large-size polycrystalline diamond film prepared by the aforementioned method.

The present disclosure has the following advantages: the method of the present disclosure enables the growth of 12-inch polycrystalline diamond films through a specific process flow, achieving thermal conductivity significantly higher than existing technologies for equivalent wafer sizes. This breakthrough directly addresses the size limitation issue in prior art, laying a foundation for applications in fields such as large-area electronic devices and optical components, etc. The technology demonstrates possible compatibility with existing silicon-based semiconductor technology, which paves the way for mass deployment of diamond films in related fields. With production scaling and process maturation, the per-unit-area production cost is expected to decrease, significantly enhancing the market competitiveness of large-area polycrystalline diamond films and accelerating industrial adoption.

### BRIEF DESCRIPTION OF THE DRAWINGS

To provide a clearer explanation of the technical solutions in the embodiments of the present disclosure, the following will briefly introduce the accompanying drawings required for describing the embodiments. It should be understood that these drawings merely illustrate certain examples of the invention and therefore should not be construed as limiting the scope. For those of ordinary skill in the art, other related drawings may be derived from these illustrations without creative efforts.

FIG. 1 is a dimensional measurement diagram of a ultra-large-size polycrystalline diamond film prepared according to Embodiment 1.

FIG. 2 is a thermal conductivity test diagram of the ultra-large-size polycrystalline diamond film prepared according to Embodiment 1.

FIG. 3 is a thermal conductivity test diagram of a ultra-large-size polycrystalline diamond film prepared according to Embodiment 4.

FIG. 4 is a thermal conductivity test diagram of a ultra-large-size polycrystalline diamond film prepared according to Embodiment 5.

### DETAILED DESCRIPTION OF THE EMBODIMENTS

To clarify the objectives, technical solutions, and advantages of the embodiments of the present disclosure, the following will describe the technical solutions of the embodiments in detail with reference to the accompanying drawings. It is to be understood that the described embodiments are merely a part of the invention and not all possible implementations. Based on the embodiments of the present disclosure, all other embodiments obtained by those of ordinary skill in the art without creative efforts shall fall within the scope of protection of the present invention. Therefore, the detailed description of the embodiments provided in the drawings is not intended to limit the claimed scope of the invention but merely illustrates selected embodiments.

An embodiment of the present disclosure provides a method for growing ultra-large-size polycrystalline diamond film, the method includes the following steps.
S1: At room temperature, a monocrystalline silicon wafer is first subject to thorough cleaning and then a drying treatment. This process aims to ensure the cleanliness of the substrate, thereby preventing contamination during subsequent growth processes.
S2: Next, the monocrystalline silicon wafer is subject to a seeding pretreatment process to deposit a diamond nanocrystalline seed layer across a silicon surface. This seed layer facilitates the subsequent growth of a high-quality polycrystalline diamond film, ensuring uniform and high-quality deposition of the polycrystalline diamond film. In this step, upon completion of the seeding pretreatment, the silicon wafer is placed in MPCVD equipment for the growth of the polycrystalline diamond film. The MPCVD equipment may adopt a quartz bell-jar configuration, with a microwave power source selected from magnetrons or solid-state generators operating at frequencies of 915 MHz or 433 MHz.
S3: Subsequently, the chamber is subject to vacuum evacuation, followed by hydrogen purging, and then re-evacuation. This series of operations aims to purify the internal environment of the chamber. Afterwards, hydrogen gas is introduced with the chamber pressure regulated to 5-8 torr, after which plasma ignition is initiated. During this step, the hydrogen flow rate is set as 50 sccm.

In the subsequent experimental steps, process parameters will be progressively adjusted to optimize growth conditions of the diamond film. First, the microwave power will be incrementally increased at a rate of 4.5-5.5 kilowatts (kW) per minute until reaching a range of 70-75 kW. This process requires precise control to ensure a stable increase of microwave power, thereby establishing a uniform energy environment for the experiment. Concurrently, the chamber pressure will be gradually elevated at a rate of 10-30 torr per minute until achieving a pressure range of 165-180 torr. This stepwise pressure increase is helpful in maintaining a stable state within the reaction chamber and ensures homogeneous distribution of reactants in the chamber.

Additionally, the temperature shall be gradually increased at a rate of 60° C. per minute until reaching a range of 900-950° C. This heating rate is critical for diamond film growth, as it enables short-duration achievement of the required high temperature while preventing thermal shock-induced damage to experimental apparatus. During this process, the synergistic interaction of elevated microwave power and reduced chamber pressure induces a substantial expansion of plasma volume. Such volumetric enlargement of plasma facilitates coverage of an expanded reaction zone, thereby promoting uniform growth of large-area diamond films.

In summary, the increase rates of microwave power, chamber pressure, and temperature exert decisive control over the growth of large-area diamond films. Through precise modulation of the adjustment rates of these parameters, the growth conditions of the diamond films can be effectively optimized, thereby achieving high-quality large-area diamond film products.
S5: Subsequently, introducing process gases for film growth with the following parameters: Hydrogen (H₂) flow rate: 5000-6000 sccm, Methane (CH₄) flow rate: 100-150 sccm, Oxygen (O₂) flow rate: 5-8 sccm, Nitrogen (N₂) flow rate: 1-2 sccm, Argon (Ar) flow rate: 800-1000 sccm. The relatively high hydrogen flow rate ensures uniform gas distribution throughout the chamber. Methane serves as the primary process gas, whereas oxygen, nitrogen, and argon function as auxiliary gases. Upon reaching the rated temperature, implement a progressive increase of process gas flow rates from zero to their rated flow rates within 10 minutes, followed by maintaining the rated flow rates for 5-10 minutes. These parameters of process gas introduction are critical for the growth quality of the diamond films. Inadequate regulation of these process gas flow rates may result in a substantial degradation of thermal conductivity of the produced diamond films.
S6: Upon completion of the growth process, initiating a cooling process with a temperature decrease rate of 30° C./min until reaching the room temperature, followed by venting the chamber with nitrogen gas to obtain said ultra-large-size polycrystalline diamond film. As the interior environment of the chamber reaches normal temperature and pressure, open the chamber to take out the obtained silicon-based polycrystalline diamond film. The present disclosure enables fabrication of ultra-large-size polycrystalline diamond films with 12-inch diameter which significantly exceeds the dimension of the diamond film of the same type achievable by conventional methods.

In some specific embodiments, the cleaning process includes sequential ultrasonic treatments of monocrystalline silicon wafer in acetone, ethanol, and deionized water, respectively, wherein the duration of the ultrasonic treatment of each cleaning agent lasts 15-30 minutes. First, the monocrystalline silicon wafer is immersed in acetone for ultrasonic cleaning to remove organic contaminants and lipid residues on surface. Subsequently, the wafer is transferred to ethanol for secondary ultrasonic cleaning to further remove residual organics and particulate matter. Finally, the wafer is put in deionized water for tertiary ultrasonic cleaning to remove ethanol residue and other possible impurities. This multi-stage ultrasonic treatment using different cleaning agents guarantees surface cleanliness of the monocrystalline silicon wafer, thereby providing a clean substrate for subsequent processes.

In some specific embodiments, the drying process is implemented via inert gas purging of monocrystalline silicon wafer. This method can effectively remove surface moisture of the wafer and achieve a dry state. Specifically, the inert gas, such as nitrogen or argon gas and so on, due to their chemically inert nature, will not react with monocrystalline silicon wafer, so they are safe to be used as purging gas. This method ensures surface dryness of wafer, thereby eliminating moisture-induced defects in subsequent production processes.

In some specific embodiments, the thickness of the diamond nanocrystalline layer is set as 10-50 nm, the precise control of the thickness range ensures that the performance of the seed layer is optimal. The seed layer with a thickness of this range not only facilitates uniform growth of polycrystalline diamond film, but also significantly enhances its quality, achieving diamond film with superior physical and chemical properties. The selection of this thickness range is based on an in-depth comprehension of diamond growth mechanisms, coupled with meticulous investigations into mutual interactions between the seed layer and diamond film. By optimizing the thickness of the seed layer, defects that are likely to occur during the growing process can be avoided, achieving high-quality polycrystalline diamond film.

In some specific embodiments, in the step of evacuating the chamber, a vacuum degree is less than 5 mtorr (millitorr, a unit used for vacuum degree measurement), and the evacuation is repeated for 3-5 times. This procedure aims to purify the chamber environment by eliminating residual impurities and gases. Through repeated evacuations, the internal pressure of the chamber is effectively reduced to achieve an ultra-clean and contamination-free environment. Such conditions are critical for the growth of polycrystalline diamond films, as they ensure uniform and high-quality deposition of polycrystalline diamond films. By doing this, the quality and performance of polycrystalline diamond films are significantly enhanced, resulting in improved stability and reliability in diverse applications.

In some specific embodiments, following step S6, the method further includes step S7. In step S7, the diamond surface of the aforementioned ultra-large-size polycrystalline diamond film undergoes precision grinding and polishing treatments to achieve a surface roughness of less than 1 nanometer (Ra<1 nm). This treatment significantly enhances the surface quality of the diamond film, resulting in a smoother finish that meets the requirements of high-precision applications.

In these embodiments, after completing step S7, the method further includes step S8. In step S8, the polished ultra-large-size polycrystalline diamond film is subject to a chemical silicon removal treatment to completely eliminate all silicon-based constituents, thereby obtaining a pure diamond film merely composed of diamond. Due to its exceptional physical and chemical properties, the pure diamond film exhibits broad application prospects in fields such as high-performance electronic devices, high-precision optical components, and wear-resistant materials under extreme environmental conditions, etc.

In these embodiments, after completing step S8, the method further comprises step S9. In step S9, the obtained pure diamond film undergoes precise picosecond laser scribing to acquire high-quality diamond wafers. Owing to their high purity and superior physical properties, these diamond wafers exhibit significant application value, especially in fields demanding high precision and high stability, such as semiconductor manufacturing, precision optics, and high-end decorative materials, etc.

In some specific embodiments, after step S6, the method further includes a step of performing precision grinding and polishing treatments on the silicon surface of the ultra-large-size polycrystalline diamond film. This step aims to partially remove silicon-based materials, thereby retaining a silicon-based layer with a thickness ranging from 5 nanometers to 10 micrometers in the final product. Through this thinning process, the thermal dissipation efficiency of the device is significantly enhanced. Specifically, the thinned silicon-based layer enables more effective heat conduction, accelerating the heat transfer from the device interior to the external environment. This improvement is particularly critical for electronic devices generating substantial heat during operation, as it ensures the devices to operate within safe and efficient temperature ranges.

The present disclosure proposes a method for fabricating ultra-large-size polycrystalline diamond films. Through a unique process flow, this method successfully grows polycrystalline diamond film with a diameter up to 12 inches, far exceeding existing technological capabilities and directly overcoming size limitations. This breakthrough lays the foundation for applications of diamond films in fields of large-area electronic devices and optical components etc. The technology satisfies the thermal dissipation demands of high-power-density devices. As electronic devices trend toward miniaturization and high performance, the power density of chips and other components continues to increase. Diamond heat spreaders can effectively response to the heat dissipation challenges under high power density, ensuring devices maintain lower temperatures during high-load operation, thereby enhancing performance, reliability, and operational lifespan of the devices. For example, diamond heat spreaders fabricated via chemical vapor deposition (CVD) are expected to achieve power densities threefold or higher than the most advanced gallium nitride (GaN) devices currently available, particularly suitable for high-power, high-frequency communication applications such as wireless communications and radar systems, etc.

Furthermore, diamond-based heat dissipation technology can optimize chip performance and operational lifespan. During chip operation, excessive temperatures lead to performance degradation, such as reduced carrier mobility, increased leakage current, and decreased breakdown voltage etc., while also shortening the chip's service life. Diamond heat dissipation effectively controls chip temperature, suppressing performance degradation and lifespan reduction caused by overheating. This ensures stable and efficient operation under high-frequency, high-power conditions, enabling full realization of the chip's performance advantages.

The high thermal conductivity of diamond further enables simpler and more efficient design of heat dissipation systems. Compared to conventional heat dissipation solutions, diamond-based heat dissipation systems is free of complex heat dissipation structures and extensive heat-dissipating components, thereby reducing the volume, weight, and cost of the heat dissipation system. This simultaneously enhances system integration and reliability, facilitating the miniaturization and lightweighting of electronic devices.

Diamond heat spreaders not only exhibit superior thermal conductivity, but also possess exceptional electrical insulation properties, mechanical strength, and thermal stability. They maintain stable performance in harsh environments characterized by high-temperature, high-pressure, and high-humidity conditions, resisting deformation, damage, or performance degradation. Consequently, in fields requiring high environmental adaptability, such as aerospace, military equipment, and industrial control systems, diamond-based heat dissipation provides reliable heat dissipation for electronic components, ensuring normal operation of devices under extreme conditions.

Finally, diamond-based heat dissipation technology overcomes the limitations of traditional heat dissipation materials. Conventional heat dissipation materials such as copper and aluminum exhibit inherent constraints in thermal performance, physical properties, or cost. For instance, while copper offers relatively high thermal conductivity, it suffers from excessive density, elevated costs, and potential electromagnetic compatibility issues in specific applications. Aluminum, with weaker heat dissipation performance, struggles to meet the heat dissipation demands of high-power devices. Diamond heat dissipation overcomes these deficiencies of traditional materials, providing a more ideal resolution for thermal challenges in high-computing-power chips and high-frequency power devices.

### Embodiment 1

A method for growing ultra-large-size polycrystalline diamond films, includes the following steps:
S1: cleaning and drying monocrystalline silicon wafers at room temperature; wherein sequential ultrasonic treatments of the monocrystalline silicon wafers in acetone, ethanol, and deionized water are carried out respectively and last 20 minutes for each cleaning agent, the drying process uses inert gas to purge the monocrystalline silicon wafers to achieve surface dryness;
S2: subjecting the monocrystalline silicon wafers to a seeding pretreatment process to deposit diamond nanocrystalline layers across silicon surfaces, then transferring the seeded monocrystalline silicon wafers into a microwave plasma chemical vapor deposition (MPCVD) equipment (UP-575 High-Power MPCVD Equipment from Shenzhen UniPlasma Plasma Technology Co., Ltd.) to get ready for diamond film growth; wherein the thickness of the diamond nanocrystalline layers is about 30 nm;
S3: evacuating a chamber of the MPCVD equipment, performing hydrogen purging, then performing re-evacuation; subsequently, introducing hydrogen gas and regulating a chamber pressure to 6 torr to initiate plasma ignition; wherein the vacuum degree of evacuation is less than 5 mtorr, and the evacuation is performed 3 times;
S4: increasing microwave power to 75 kW with a rate of 5 kW/min, elevating the chamber pressure to 170 torr with a rate of 15 torr/min, and increasing chamber temperature to 920° C. with a rate of 60° C./min;
S5: introducing growth gases with the following flow rates: hydrogen (H₂) at 5500 sccm, methane (CH₄) at 125 sccm, oxygen (O₂) at 6 sccm, nitrogen (N₂) at 1.5 sccm, and argon (Ar) at 900 sccm, upon reaching the rated temperature, progressively increase the process gas flow rate from 0 sccm to the rated flow rate within 10 minutes, and maintain the rated flow rate for 8 minutes;
S6: upon completion of diamond growth, initiating a cooling process with a temperature decrease rate of 30° C./min until room temperature is reached, followed by venting the chamber with nitrogen gas, thereby obtaining the ultra-large-size polycrystalline diamond films.

The measurement of the dimension of the ultra-large-size polycrystalline diamond film was conducted, with measurement results shown in FIG. 1. As demonstrated in FIG. 1, the diameter of the ultra-large-size polycrystalline diamond film reaches approximately 12 inches (30.48 cm).

### Comparative Example 1

The Comparative Example 1 differs from Embodiment 1 in Step S4, in the Comparative Example 1, the microwave power is increased to 75 KW at a rate of 2 kW/min, the chamber pressure is elevated to 220 torr at a rate of 30 torr/min, and the temperature is increased to 920° C. at rate of 100° C./min, while other operational parameters remain identical to Embodiment 1.

Dimension of the polycrystalline diamond film was measured, yielding a diameter of about 5 inches.

### Comparative Example 2

The Comparative Example 2 differs from Embodiment 1 in Step S4, in the Comparative Example 2, the microwave power is increased to 75 KW at a rate of 2 kW/min, the chamber pressure is elevated to 240 torr at a rate of 30 torr/min, and the temperature is increased to 920° C. at rate of 100° C./min, while other operational parameters remain identical to Embodiment 1.

Dimension of the polycrystalline diamond film was measured, yielding a diameter of about 4 inches.

### Comparative Example 3

The Comparative Example 3 differs from Embodiment 1 in Step S4, in the Comparative Example 3, the microwave power is increased to 75 KW at a rate of 2 kW/min, the chamber pressure is elevated to 200 torr at a rate of 30 torr/min, and the temperature is increased to 920° C. at rate of 100° C./min, while other operational parameters remain identical to Embodiment 1.

Dimension of the polycrystalline diamond film was measured, yielding a diameter of about 7 inches.

### Comparative Example 4

The Comparative Example 4 differs from Embodiment 1 in Step S5, in the Comparative Example 4, process gases are introduced at the following flow rates: Hydrogen: 2500 sccm, Methane: 50 sccm, Oxygen: 6 sccm, Nitrogen: 1.5 sccm, Argon: 900 sccm, while other operational parameters remain identical to Embodiment 1.

Dimension of the polycrystalline diamond film was measured, yielding a diameter of about 12 inches.

### Comparative Example 5

The Comparative Example 5 differs from Embodiment 1 in Step S5, in Comparative Example 5, process gases are introduced at the following flow rates: Hydrogen: 5500 sccm, Methane: 125 sccm, Oxygen: 15 sccm, Nitrogen: 5 sccm, Argon: 900 sccm, while other operational parameters remain identical to Embodiment 1.

Dimension of the polycrystalline diamond film was measured, yielding a diameter of about 12 inches.

### Embodiment 2

In Embodiment 2, after Step S6, the method further includes Step S7: grinding and polishing the diamond surface of the ultra-large-size polycrystalline diamond film to achieve Ra<1 nm surface roughness.

After Step S7, the method further includes Step S8: subjecting the polished ultra-large-size polycrystalline diamond film to chemical silicon removal to substantially remove the silicon substrate, thereby obtaining a pure diamond film.

After Step S8, the method further includes Step S9: the pure diamond film undergoing UV picosecond laser scribing then subject to dicing by a dicing machine to produce a high-quality diamond wafer.

### Embodiment 3

In Embodiment 3, after the Step S6, the method further includes grinding and polishing a silicon surface of the ultra-large-size polycrystalline diamond film to achieve partial silicon removal while retaining a silicon substrate with a thickness of 5 nm-10 μm.

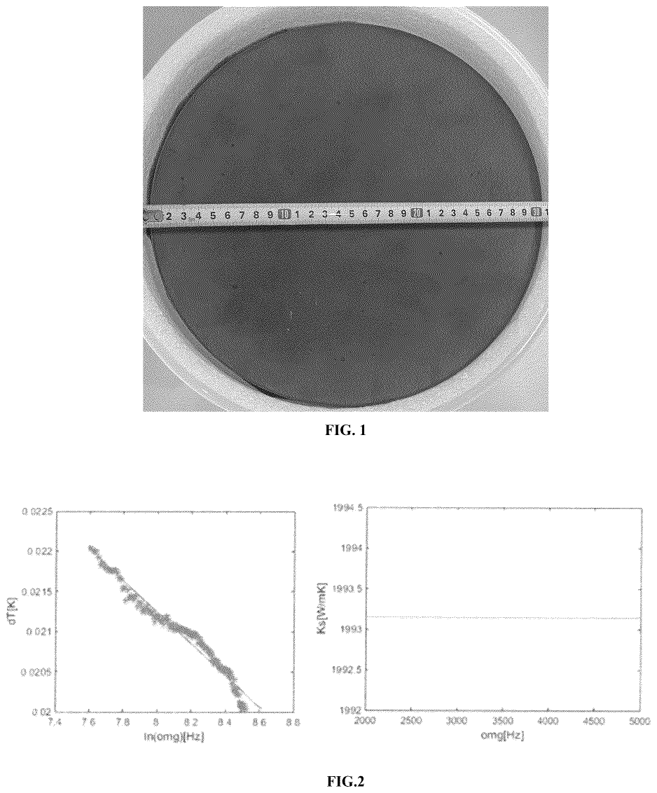

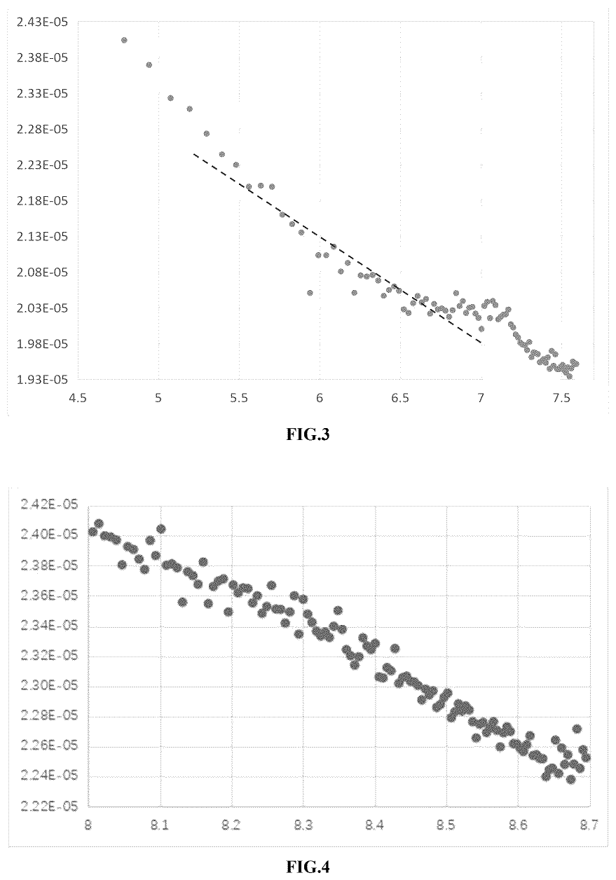

The thermal conductivity of polycrystalline diamond films prepared by Embodiment 1 and Comparative Examples 4 and 5 was measured using the 3ω electrical testing technique under a testing temperature of 25° C.±10° C. The test results are shown in FIGS. 2-4 and Table 1.

TABLE 1

| | Thermal |
|---|---|
| Embodiment | Conductivity/W/mK |
| Embodiment 1 | 1993.2 |
| Comparative | 1236.6 |
| Example 4 | |
| Comparative | 1283.5 |
| Example 5 | |

A comparative analysis between Embodiment 1 and Comparative Examples 1-3 clearly demonstrates that the polycrystalline diamond film prepared in Embodiment 1 exhibits significantly superior diameter compared to the samples from Comparative Examples 1-3. This result clearly indicates that critical process parameters such as microwave power and chamber pressure play a decisive role in governing the growth area of polycrystalline diamond film during their growth. Specifically, properly reducing the chamber pressure while synchronously elevating the microwave power can effectively expand the plasma volume, thereby promoting uniform growth of the polycrystalline diamond film over a larger area and ultimately achieving a substantial enhancement in the overall growth area.

Further analysis of the data listed in Table 1 reveals that the polycrystalline diamond film of Embodiment 1 exhibits comparable dimensions to the samples of Comparative Examples 4-5, yet demonstrates a significant superiority in the critical performance index of thermal conductivity, with values far exceeding those of Comparative Examples 4-5. This phenomenon highlights an important insight: during the growth process of polycrystalline diamond films, optimization of process gas parameters plays a decisive role in ensuring their deposition quality. Although the samples of Comparative Examples 4-5 can also achieve large-size polycrystalline diamond films, improper regulation of process gas parameters leads to a substantial reduction in thermal conductivity, even failing to meet qualification standards, thereby severely limiting their practical performance and applicability. Consequently, optimizing process gas parameters is a pivotal step for enhancing the comprehensive performance of polycrystalline diamond films.

The foregoing descriptions merely represent the preferred embodiments of the present disclosure and are not intended to limit the scope of the invention. For those skilled in the art, the present disclosure may have various modifications and variations. Any modifications, equivalent substitutions, and improvements made within the spirit and principles of the present invention shall fall within the protection scope of the present disclosure.

1. A method for growing ultra-large-size polycrystalline diamond film, comprising the following steps:
S1: cleaning and drying a monocrystalline silicon wafer at room temperature;
S2: subjecting the monocrystalline silicon wafer to a seeding pretreatment process to deposit a diamond nanocrystalline layer across a silicon surface, then transferring the seeded monocrystalline silicon wafer into a microwave plasma chemical vapor deposition (MPCVD) equipment, wherein the MPCVD equipment has a microwave source of 915 MHz or 433 MHz;
S3: evacuating a chamber of the MPCVD equipment, performing hydrogen purging, then performing re-evacuation; subsequently, introducing hydrogen gas and regulating a chamber pressure to 5-8 torr to initiate plasma ignition;
S4: increasing microwave power to 70-75 kW with a rate of 4.5-5.5 kW/min, elevating the chamber pressure to 165-180 torr with a rate of 10-30 torr/min, and increasing chamber temperature to 900-950° C. with a rate of 60° C./min;
S5: introducing growth gases with the following flow rates: hydrogen (H₂) at 5000-6000 sccm, methane (CH₄) at 100-150 sccm, oxygen (O₂) at 5-8 sccm, nitrogen (N₂) at 1-2 sccm, and argon (Ar) at 800-1000 sccm; and
S6: upon completion of diamond growth, initiating a cooling process with a temperature decrease rate of 30° C./min until the room temperature is reached, followed by venting the chamber with nitrogen gas, thereby obtaining the ultra-large-size polycrystalline diamond film.

2. The method for growing ultra-large-size polycrystalline diamond film of claim 1, wherein the cleaning process comprises sequential ultrasonic treatments of the monocrystalline silicon wafer in acetone, ethanol, and deionized water, respectively, and each treatment lasts for 15-30 minutes.

3. The method for growing ultra-large-size polycrystalline diamond film of claim 1, wherein the drying process comprises blow-drying the monocrystalline silicon wafer with inert gas to achieve surface dryness.

4. The method for growing ultra-large-size polycrystalline diamond film of claim 1, wherein the diamond nanocrystalline layer has a thickness of 10-50 nm.

5. The method for growing ultra-large-size polycrystalline diamond film of claim 1, wherein in the step of evacuating the chamber, a vacuum degree is less than 5 mtorr, and the evacuation is repeated for 3-5 times.

6. The method for growing ultra-large-size polycrystalline diamond film of claim 1, wherein after the step S6, the method further comprises S7, grinding and polishing a diamond surface of the ultra-large-size polycrystalline diamond film to achieve a surface roughness of ra<1 nm.

7. The method for growing ultra-large-size polycrystalline diamond film of claim 6, wherein after the step S7, the method further comprises S8, the polished ultra-large-size polycrystalline diamond film undergoing chemical silicon removal to substantially remove a silicon substrate and yield a pure diamond film.

8. The method for growing ultra-large-size polycrystalline diamond film of claim 7, wherein after the step S8, the method further comprises S9, the pure diamond film undergoing picosecond laser scribing to produce a high-quality diamond wafer.

9. The method for growing ultra-large-size polycrystalline diamond film of claim 1, wherein after Step S6 the method further comprises grinding and polishing a silicon surface of the ultra-large-size polycrystalline diamond film to achieve partial silicon removal while retaining a silicon substrate with a thickness of 5 nm to 10 μm.

10. A ultra-large-size polycrystalline diamond film prepared by the method of any one of claims 1 to 9, characterized in that the size thereof is 12 inches.
